(19) United States
(12) Patent Application Publication
(10) Pub. No.: US 2025/0087478 A1
(43) Pub. Date: Mar. 13, 2025

(54) METHODS FOR FORMING A METAL SILICATE LAYER FOR CONTROLLING A THRESHOLD VOLTAGE OF A METAL-OXIDE-SEMICONDUCTOR FIELD EFFECT TRANSISTOR

(71) Applicant: ASM IP Holding B.V., Almere (NL)

(72) Inventors: Patricio Eduardo Romero, Wilsele (BE); Charles Dezelah, Helsinki (FI)

(21) Appl. No.: 18/883,125

(22) Filed: Sep. 12, 2024

Related U.S. Application Data
(60) Provisional application No. 63/582,397, filed on Sep. 13, 2023.

(51) Int. Cl. H01L 21/02

(52) U.S. Cl. CPC H01L 21/02208; H01L 21/02142

(57) ABSTRACT

Methods for forming a metal silicate layer for controlling a threshold voltage of metal-oxide semiconductor field effect transistor (MOSFET) are disclosed. The methods include forming a metal silicate threshold adjusting layer on a substrate by contacting the substrate with a precursor comprising an organosilanol precursor or a siloxide precursor.

### CROSS-REFERENCE TO RELATED APPLICATION(S)

This application claims the benefit of U.S. Provisional Application 63/582,397 filed on Sep. 13, 2023, the entire contents of which are incorporated herein by reference.

### FIELD

The present disclosure relates generally to the field of semiconductor processing methods and associated semiconductor structures, and to the field of device and integrated circuit manufacture. More particularly, the present disclosure relates to methods for forming layers that allow for the control of the threshold voltage of metal-oxide-semiconductor field-effect transistors (MOSFETs) and to structures formed using such methods.

### BACKGROUND OF THE DISCLOSURE

The scaling of semiconductor devices, such as, for example, complementary metal-oxide-semiconductor (CMOS) devices, has led to significant improvements in speed and density of integrated circuits. However, conventional device scaling techniques face significant challenges in future technology nodes. For example, one challenge has been finding suitable gate stack materials, i.e., the materials that form the device layers between a gate and a channel of a field effect transistor. One particular problem in this regard is controlling the threshold voltage of field effect transistors. Accordingly, improved methods for forming threshold voltage adjustments layers, also referred to as “dipole layers”, are desirable.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary may introduce a selection of concepts in a simplified form, which may be described in further detail below. This summary is not intended to necessarily identify key features or essential features of the claimed subject matter, nor is it intended to be used to limit the scope of the claimed subject matter.

Various embodiments of the present disclosure relate to methods for forming a metal silicate layer for controlling the threshold voltage of metal-oxide-semiconductor field effect transistor (MOSFET). Such threshold voltage control is provided by the formation of ultra-thin dipole layers and particularly ultra-thin dipole layers comprising metal silicates. The dipole layers can be used in a variety of applications, including in the formation of a gate stacks.

In more details, next generation transistor device structures (e.g., MOSFETS and the like) may require multi-threshold voltage (Vₜₕ) schemes. The need for such multiple Vₜₕ devices will increase the need for dipole layers to fine tune the effective work function (eWF) of the gate stack of the devices. However, with decreases in device dimensions and the subsequent reduction in the layer thicknesses of the layers making up the gate stack, ultra-thin dipole layers will be needed.

Accordingly, in some embodiments of the present disclosure, the metal silicate dipole layers formed by the methods of the present disclosure can operate effectively in controlling/adjusting the threshold voltage of a field effect transistor while employing metal silicate layers with an average layer thicknesses of less than 0.1 nanometers, and in some embodiments such metal silicate layers may not comprise a fully closed layer.

In addition, the present disclosure provides metal silicates layers having a general formula MSiₓO_{y}, where M is a metal element, Si is silicon, O is oxygen, and x and y indicate the composition of the metal silicate layer. In addition, some embodiments of present disclosure provide improved methods for forming such metal silicate layers by removing the need for an additional oxidizing agent (e.g., O₂, H₂O, etc.) during the formation of the metal silicate layers. For example, when additional oxidizing agents are used as a reactant in the formation of a metal silicate dipole layer, additional oxygen content can be introduced into the gate stack, leading to potential increases in the equivalent oxide thickness (EOT) and a subsequent penalty in the electrical performance of the device structure.

In accordance with examples of the disclosure, a method of forming a metal silicate layer for controlling a threshold voltage of a metal-oxide-semiconductor field effect transistor (MOSFET) is provided. An exemplary method includes seating a substrate within a reaction chamber, the substrate including a dielectric surface, performing a pre-deposition treatment on the dielectric surface to form a treated dielectric surface, and forming a metal silicate threshold voltage shifting layer directly on the treated dielectric surface by contacting the treated dielectric surface with a precursor including a siloxide precursor or an organosilanol precursor.

In some embodiments, the dielectric surface includes a silicon oxide surface.

In some embodiments, the pre-deposition treatment can include contacting the silicon oxide surface with a metal catalyst, the metal catalyst including a metal element selected from a group consisting of rare earth elements, Zr, Al, Ga, Ti, Mg, Hf, Ta, V, Nb, Sr, Ca, and Ba.

In accordance with examples of the disclosure, the organosilanol precursor can include both an —OH group and an —OR group attached to a silicon atom, where R comprises a linear or branched C1-C10 alkyl group. In such examples, the organosilanol precursor can include at least one alkoxy group and a —OH group attached to a silicon atom. In such examples, the organosilanol precursor can include three alkoxy groups and a —OH group attached to a silicon atom. In such examples, the organosilanol precursor can be selected from a group consisting of tris(tert-butoxy)silanol (TBS), tris(iso-propoxy)silanol (TIS), and tris(tert-pentoxy)silanol (TPS).

In accordance with examples of the disclosure, the siloxide precursor can include a single source precursor having the general formula M(OSiR₁R₂R₃)ₓL_{y}, where M is a metal, and each of R₁-R₃ are independently selected from a C1-10 alkyl group or a C1-10 alkoxyl group, where L is an organic ligand, and where y is equal to zero or greater than zero and the sum of x and y is equal to a valence of the metal (M). In some embodiments, the siloxide precursor can have the general formula M[OSi(O^{t}Bu)₃]₄ where M is a metal selected from the group consisting of Al, Ga, Ti, Hf, and Zr.

In accordance with additional examples of the disclosure, a method of forming a metal silicate layer for controlling a threshold voltage of a metal-oxide-semiconductor field effect transistor (MOSFET) is provided. An exemplary method includes seating a substrate within a reaction chamber, the substrate comprising a dielectric surface including a silicon oxide surface and/or a high-k dielectric surface, and depositing a metal silicate threshold voltage shifting layer directly on the dielectric surface by contacting the dielectric surface with a metal siloxide precursor, the metal siloxide precursor including a single source precursor having one or more silicon atoms, metal atoms, and oxygen atoms.

In accordance with such examples, the metal siloxide precursor can have the general formula M(OSiR₁R₂R₃)ₓL_{y}, where M is a metal selected from a group consisting of rare earth elements, Zr, Al, Ga, Ti, Mg, Hf, Ta, V, Nb, Sr, Ca, and Ba, and where each of R₁-R₃ are independently selected from a C1-10 alkyl group or a C1-10 alkoxy group, where L is an organic ligand, and where y is equal to zero or greater than zero, and the sum of x and y is equal to a valence of the metal.

In some embodiments, the metal siloxide precursor is a homoleptic siloxide precursor. In such embodiments, the homoleptic siloxide precursor can be selected from a group consisting of tetrakis(trimethylsiloxide)Zr, and tetrakis(trimethylsiloxide)Hf.

In some embodiments, the siloxide compound is a heteroleptic siloxide precursor. In such embodiments, the heteroleptic siloxide compound can include the organic ligand (L), where L is selected from a group consisting of Cp (cyclopentadienyl) ligands, acac (acetylacetonate) ligands, and 2,2,6,6-tetramethylheptane-3,5-dionate (thd) ligands. In such embodiments, the heteroleptic siloxide precursor is selected from a group consisting of Zr bis(trimethylsiloxide) bis(thd), and Hf bis(trimethylsiloxide) bis(thd).

In accordance with additional examples of the disclosure, a method for depositing a threshold voltage shifting layer on a dielectric surface is provided wherein the threshold voltage shifting layer has a chemical formula containing a metal element, a silicon element, and an oxygen element, wherein a single source precursor comprising a metal siloxide precursor is used as a source for the metal element, the silicon element, and the oxygen element, and wherein the dielectric surface comprises a silicon oxide surface and/or a high-k dielectric surface. In such examples, the metal siloxide precursor can have a general formula M[OSi(O^{t}Bu₃)]₄ where M is a metal selected from the group consisting of Al, Ga, Ti, Hf, and Zr. In such examples, the threshold voltage adjustment layer is selected from a group consisting of an aluminum silicate, a gallium silicate, a titanium silicate, a hafnium silicate, and a zirconium silicate.

Other technical features may be readily apparent to one skilled in the art from the following figures, descriptions, and claims. These and other embodiments will become readily apparent to those skilled in the art from the following detailed description of certain embodiments having reference to the attached figures. The invention is not being limited to any particular embodiments disclosed.

### BRIEF DESCRIPTION OF THE DRAWINGS

To easily identify the discussion of any particular element or act, the most significant digit or digits in a reference number refer to the figure number in which that element is first introduced.

A more complete understanding of the embodiments of the present disclosure may be derived by referring to the detailed description and claims when considered in connection with the following illustrative figures.

FIG. 1 illustrates a method in accordance with exemplary embodiments of the disclosure; and

FIGS. 2A-C illustrate exemplary structures in accordance with embodiments of the disclosure.

FIGS. 3A-C illustrate further exemplary structures in accordance with embodiments of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The description of exemplary embodiments of methods, structures, devices, and apparatus provided below is merely exemplary and is intended for purposes of illustration only; the following description is not intended to limit the scope of the disclosure or the claims. Moreover, recitation of multiple embodiments having stated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other.

As set forth in more detail below, various embodiments of the disclosure provide methods for forming metal silicate layers suitable for a variety of applications. Exemplary methods can be used, for example, to form dipole layers comprising metal silicates suitable for metal-oxide-semiconductor (MOS) applications, such as in the formation of complimentary MOS (CMOS) devices. For example, metal silicate dipole layers can be used in the formation of logic devices, dynamic random-access memory (DRAM), three-dimensional NAND devices. However, unless noted otherwise, the invention is not necessarily limited to such examples.

As used herein, the terms “precursor” and “reactant” can refer to molecules (compounds or molecules comprising a single element) that participate in a chemical reaction that produces another compound. A precursor typically contains portions that are at least partly incorporated into the compound or element resulting from the chemical reaction in question. Such a resulting compound or element may be deposited on a substrate. A reactant may be an element or a compound that is not incorporated into the resulting compound or element to a significant extent. In some cases, the term reactant can be used interchangeably with the term precursor.

As used herein, the term “organosilanol precursor” can refer to a compound or complex including an organic component, and one or more silicon atoms, and oxygen atoms.

As used herein, the term “siloxide precursor” can refer to a compound or complex including an organic component, and one or more silicon atoms, metal atoms, and oxygen atoms.

As used herein, the term “layer” and “film” can refer to any continuous or non-continuous structure and material, such as material formed and/or deposited by the methods disclosed herein. For example, a layer (or film) can include two-dimensional materials, three-dimensional materials, nanoparticles or even partial or full molecular layers or partial or full atomic layers or clusters of atoms and/or molecules. A layer may comprise material or a layer with pinholes. A layer may be at least partially continuous. A layer may be patterned, e.g., subdivided, and may be comprised of a plurality of semiconductor devices.

As used herein, the term “substrate” can refer to any underlying material or materials that can be used to form, or upon which, a device, a circuit, or a film can be formed by means of a method according to an embodiment of the present disclosure. A substrate can include a bulk material, such as silicon (e.g., single-crystal silicon), other Group IV materials, such as germanium, or other semiconductor materials, such as Group II-VI or Group III-V semiconductor materials, and can include one or more layers overlying or underlying the bulk material. Further, the substrate can include various features, such as recesses, protrusions, and the like formed within or on at least a portion of a layer of the substrate. By way of example, a substrate can include bulk semiconductor material and an insulating or dielectric material layer overlying at least a portion of the bulk semiconductor material. Further, the term “substrate” may refer to any underlying material or materials that may be used, or upon which, a device, a circuit, or a film may be formed. The “substrate” may be continuous or non-continuous; rigid or flexible; solid or porous. The “substrate” may be in any form such as a powder, a plate, or a workpiece. Substrates in the form of a plate may include wafers in various shapes and sizes. Substrates may be made from materials, such as silicon, silicon germanium, silicon oxide, gallium arsenide, gallium nitride and silicon carbide for example. A continuous substrate may extend beyond the bounds of a process chamber where a deposition process occurs and may move through the process chamber such that the process continues until the end of the substrate is reached. A continuous substrate may be supplied from a continuous substrate feeding system allowing for manufacture and output of the continuous substrate in any appropriate form. Non-limiting examples of a continuous substrate may include a sheet, a non-woven film, a roll, a foil, a web, a flexible material, a bundle of continuous filaments or fibers (i.e., ceramic fibers or polymer fibers). Continuous substrates may also comprise carriers or sheets upon which non-continuous substrates are mounted. By way of examples, a substrate can include semiconductor material. The semiconductor material can include or be used to form one or more of a source, drain, or channel region of a device. The substrate can further include an interlayer dielectric (e.g., silicon oxide) and/or a high dielectric constant material layer overlying the semiconductor material. In this context, high dielectric constant material (or high k dielectric material) is a material having a dielectric constant greater than the dielectric constant of silicon dioxide.

As used herein, the term “structure” and “semiconductor structure” can be or include a substrate as described herein. Structures can include a substrate and one or more layers overlying the substrate, such as one or more layers formed by a method according to the current disclosure. The structure may include or be used in the formation of, for example, a via or a line in BEOL processing, or a contact or a local interconnect in MEOL processing. The structure may also be used to form a layer in a gate stack, a gate electrode, a buried power rail in logic applications, as well as a word line or a bit line in an advanced memory application. A “structure” can also include fabricated and/or partially fabricated device structures, such as, transistor, memory, and/or logic elements.

Further, in this disclosure, any two numbers of a variable can constitute a workable range of the variable, and any ranges indicated may include or exclude the endpoints. Additionally, any values of variables indicated (regardless of whether they are indicated with “ ” or not) may refer to precise values or approximate values and include equivalents, and may refer to average, median, representative, majority, or the like. Further, in this disclosure, the terms “including,” “constituted by” and “having” refer independently to “typically or broadly comprising,” “comprising,” “consisting essentially of,” or “consisting of” in some embodiments. In this disclosure, any defined meanings do not necessarily exclude ordinary and customary meanings in some embodiments.

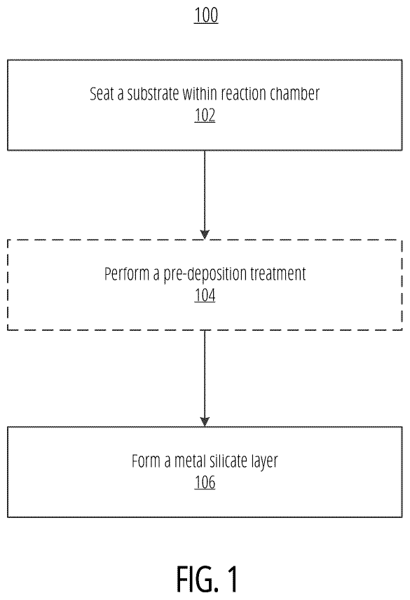

Turning now to the figures, FIG. 1 illustrates an exemplary method 100. Method 100 includes the steps of seating a substrate within a reaction chamber, the substrate including a dielectric surface (step 102), optionally performing a pre-deposition treatment on the dielectric surface (step 104), and forming a metal silicate threshold voltage shifting layer on the dielectric surface (step 106).

During step 102, a substrate is seated within a reaction chamber. The reaction chamber used during step 102 can be or include a reaction chamber of a chemical vapor deposition reactor system configured to perform a chemical vapor deposition process or a cyclical deposition process. In some embodiments, the reaction chamber used during step 102 can be or include a reaction chamber of an atomic layer deposition reactor configured to perform a cyclical deposition process, such as, an atomic layer deposition process. In some embodiments, the reaction chamber used during step 102 can be or include a reaction chamber of a plasma-enhanced atomic layer deposition reactor system. In some embodiments, the reaction chamber used during step 102 can be or include a reaction chamber of an plasma-enhanced chemical vapor deposition reactor system.

The reaction chamber can be a standalone reaction chamber or part of a cluster tool. The reaction chamber can include a substrate heater to heat a substrate to a substrate temperature noted herein.

In accordance with examples of the disclosure, the substrate seated within the reaction chamber during step 102 can include a dielectric layer. In such examples, the substrate includes a dielectric surface. In some embodiments, dielectric layer can comprise a silicon oxide and/or a high-k dielectric. In such examples, the substrate comprises a silicon oxide surface and/or a high-k dielectric surface.

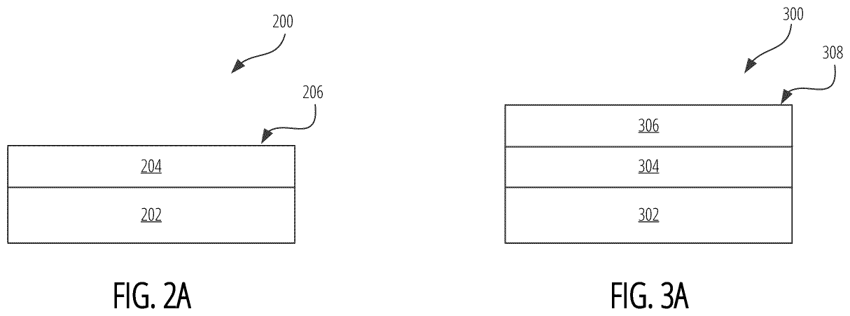

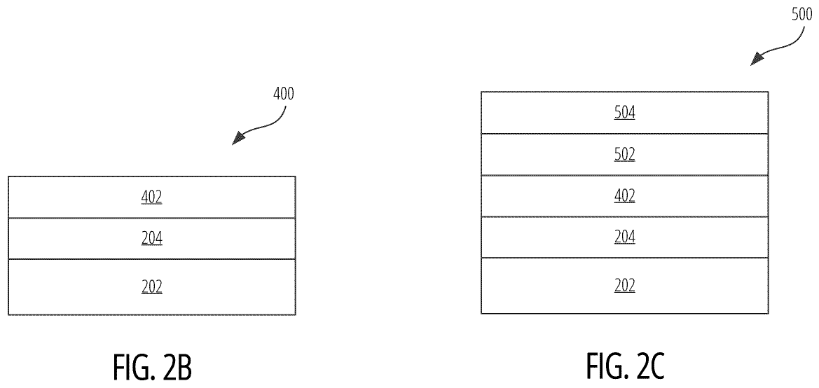

FIG. 2A illustrates a portion of an exemplary substrate suitable for use as a substrate during step 102. Substrate 200 includes a semiconductor body 202 and a dielectric layer 204 disposed on the semiconductor body 200. The dielectric layer 204 includes a dielectric surface 206. In accordance with examples of the disclosure, the dielectric layer 204 can comprise a silicon oxide layer. In such examples, the dielectric surface 206 is a silicon oxide surface. In accordance with examples of the disclosure, the substrate 200 can form part of a partially fabricated semiconductor device structure, such as, a field effect transistor. In such examples, the underlying region of the semiconductor body 202 adjacent to the dielectric layer 204 can include a channel region of a semiconductor device structure.

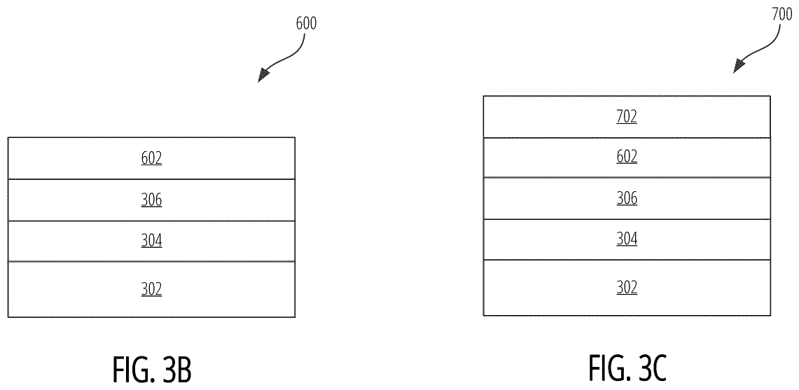

FIG. 3A illustrates a portion of an additional substrate suitable for use as a substrate during step 102. Substrate 300 includes a semiconductor body 302 and a dielectric layer 304 disposed on the semiconductor body. The dielectric layer 304 can function as an interface dielectric layer. In such examples, the interface layer can comprise a silicon oxide layer. Substrate 300 includes a high-k dielectric layer 306 disposed on the dielectric layer 304. The high-k dielectric layer 306 includes a dielectric surface 306. In such examples, the dielectric surface 306 is a high-k dielectric surface. Exemplary high-k dielectric surfaces include, but are not limited to, hafnium oxide (HfO₂), tantalum oxide (Ta₂O₅), zirconium oxide (ZrO₂), titanium oxide (TiO₂), hafnium silicate (HfSiOₓ), aluminum oxide (Al₂O₃), lanthanum oxide (La₂O₃), and mixtures/laminates comprising one or more such layers. In accordance with examples of the disclosure, the substrate 300 can form part of a partially fabricated semiconductor device structure, such as, such as, a field effect transistor. In such examples, the underlying region of the semiconductor body 302 adjacent to the dielectric layer 304 can include a channel region of a semiconductor device structure.

Once the substrate is seated within the reaction chamber (step 102), the method 100 (FIG. 1) can continue with the optional step of performing a pre-deposition treatment on the dielectric surface to form a treated dielectric surface (step 104). In accordance with examples of the disclosure, the optional pre-deposition treatment (or treatments) can include, but is not limited to, a cleaning treatment, a surface preparation treatment, a surface functionalizing treatment, or a surface catalyzation treatment.

In accordance with examples of the disclosure, the metal silicate layers of the present disclosure can be formed by performing a pre-deposition treatment on the dielectric surface upon which the metal silicate layer is to be formed and subsequently contacting the treated surface with either an organosilanol precursor or a siloxide precursor. Therefore, in the interest of clarity, the subsequent description includes “Section A”, which details the embodiments of the disclosure that employ organosilanol precursors in the formation of the metal silicate layer and “Section B”, which details the embodiments of the disclosure that employ siloxide precursors in the formation of the metal silicate layers. In addition, “Section C” details the properties of the metal silicate layers formed by the methods of the present disclosure as well as structures including such metal silicate layers.

### Section A: Metal Silicate Formation by Catalyzation and Organosilanol Precursors

In accordance with examples of the disclosure, the metal silicate layers of the present disclosure can be formed by pretreating a dielectric surface, upon which the metal silicate layer is to be formed. In such examples, the dielectric surface can be treated with a metal catalyst. In such examples, the metal catalyst can provide the metal component for the metal silicate layer, i.e., the metal element in the metal silicate layer is provided by the metal catalyst via the catalyzation of the dielectric surface. In other examples, the metal catalyst can simply act as a catalyst in the formation of the metal silicate, with the metal component of the metal silicate layer not being provided by the metal catalyst, rather the metal component of the metal silicate layer can be provided by a separate metal containing precursor.

In accordance with examples of the disclosure, once the treated dielectric surface is catalyzed via the metal catalyst, the methods of the disclosure can subsequently contact the catalyzed surface with an organosilanol precursor thereby forming the metal silicate layer, i.e., step 106 of method 100 (FIG. 1). In such examples, the organosilanol precursor provides both the silicon component and the oxygen component of the metal silicate layer.

Therefore, in accordance with some examples of the disclosure, the substrate can include a silicon oxide surface (as illustrated by substrate 200 of FIG. 2). In such examples the pre-deposition treatment can comprise a surface catalyzation. In accordance with examples of the disclosure, a catalyst is formed on the silicon oxide surface, such as by contacting the surface with a catalyst compound or complex. Such a treated surface may be referred to as herein as a “catalyzed silicon oxide surface”.

In accordance with examples of the disclosure, the catalyst is a metal catalyst. In some embodiments the dielectric surface, e.g., a silicon oxide surface, is contacted with a metal catalyst as described below. In some embodiments, the metal catalyst is a metal compound or metal complex comprising one or more of rare earth elements, Zr, Al, Ga, Ti, Mg, Hf, Ta, V, Nb, Sr, Ca, and Ba. In some embodiments the catalyst is a metal halide, organometallic or metalorganic compound comprising one or more of rare earth elements, Zr, Al, Ga, Ti, Mg, Hf, Ta, V, Nb, Sr, Ca, and Ba. In accordance with further examples of the disclosure, the pre-deposition treatment n the dielectric surface can include contacting the dielectric surface, e.g., a silicon oxide surface, with a metal catalyst including a metal element selected from a group consisting of rare earth elements, Zr, Al, Ga, Ti, Mg, Hf, Ta, V, Nb, Sr, Ca, and Ba.

In some embodiments, the catalyst is a compound comprising boron. In some embodiments the catalyst is an alkylaluminium, alkylboron or alkylzinc compound that is able to react with a hydrophobic silicon oxide surface. For example, the catalyst may comprise trimethyl aluminum (TMA), triethylboron (TEB), or diethyl zinc. In some embodiments the catalyst comprises a compound having the formula MRₓA₃₋ₓ, wherein x is an integer from 1 to 3, R is a C1-C5 alkyl ligand, M is a rare earth elements, Zr, Al, Ga, Ti, Mg, Hf, Ta, V, Nb, Sr, Ca, or Ba, and A is a halide, alkylamine, amino, silyl or derivative thereof. In some embodiments the R is a C1-C3 alkyl ligand. In some embodiment the R is a methyl or ethyl group. In some embodiments the M is boron. In some embodiments the catalyst is ZnRₓA₂₋ₓ, wherein x is an integer from 1 to 2, R is a C1-C5 alkyl ligand, and A is a halide, alkylamine, amino, silyl or derivative thereof. In some such embodiments the R is a C1-C3 alkyl ligand. In some embodiment the R is a methyl or ethyl group.

In some embodiments the metal catalyst is an aluminum catalyst comprising one or more of trimethyl aluminum (TMA), dimethylaluminumchloride, aluminum trichloride (AlCl₃), dimethylaluminum isopropoxide (DMAI), tris(tert-butyl) aluminum (TTBA), tris(isopropoxide) aluminum (TIPA) or triethyl aluminum (TEA).

In some embodiments the catalyst is a zirconium catalyst comprising one or more of bis(methylcyclopentadientyl)methyl(methoxy)zirconium (Zr(MeCp)2(Me)(OMe)), tetrakis(ethylmethylamino)zirconium (TEMAZ), ZrCp(NMe₂)₃, Zr(MeCp)₂(Me)₂, Zr(MeCp)₂(OMe)₂, or ZrCl₄.

In some embodiments the catalyst is a lanthanum catalyst, such as tris(isopropyl-cyclopentadienyl)lanthanum (La(iPrCp)₃).

In some embodiments the catalyst is a titanium catalyst, such as titanium isopropoxide (TTIP) or TiCl₄.

In some embodiments the catalyst is a gallium catalyst comprising one or more of GaCl, GaCl₃, (GaMe₂NH₂)₃, Ga(acac)₃, Ga(CpMe₅), Ga(thd)₃, Ga₂(NMe₂)₆, GaEt₃, GaMe₂(OⁱPr), GaMe₂NH₂, GaMe₃, or GaMe₃(CH₃OCH₂CH₂NH^{t}Bu).

In some embodiments the catalyst is a hafnium catalyst comprising one or more of HfCl₄, Hf(NO₃)₄, bis(methylcyclopentadientyl)methyl(methoxy)hafnium (Hf(MeCp)2(Me)(OMe)), tetrakis(ethylmethylamino)hafnium (TEMAZ), HfCp(NMe₂)₃, Hf(MeCp)₂(Me)₂, or Hf(MeCp)₂(OMe)₂.

In accordance with examples of the disclosure, the catalyst may be provided to the reaction chamber in a single pulse or in a sequence of multiple pulses. In some embodiments the catalyst is provided in a single long pulse or in multiple shorter pulses. The pulses may be provided sequentially. In some embodiments the catalyst is provided in 1 to 25 pulses of from 0.1 to 60 seconds. In some embodiments the catalyst is provided in a single pulse of 0.1 to 60 seconds, or 1 to 30 seconds, or about 25 seconds. In between pulses, excess catalyst may be removed from the reaction space. For example, the reaction chamber may be evacuated and/or purged with an inert gas. The purge may be, for example for 1 to 30 seconds or more. Purging means that vapor phase catalyst and/or vapor phase byproducts, if any, are removed from the reaction chamber such as by evacuating the chamber with a vacuum pump and/or by replacing the gas inside the reaction chamber with an inert gas. In some embodiments a vapor phase catalyst is removed from the substrate surface by moving the substrate from the reaction space comprising the vapor phase catalyst.

In some embodiments, the temperature of the substrate during step 104 e.g., during the formation of the catalyzed silicon oxide surface, may be, for example, from 50° C. to 500° C., or from 100° C. to 300° C. In some embodiments, the substrate temperature is between 50° C. and 400° C. In some embodiments the temperature of the substrate is greater than 100° C. and the catalytic chemical is an alkylaluminum compound, such as TMA. In some embodiments, the alkylaluminum compound is dimethylaluminum isopropoxide (DMAI), and the substrate temperature is from 100° C. to 400° C., or from 100° C. to 200° C., or from 200° C. to 400° C., or from 250° C. to 350° C. In some embodiments, the alkylaluminum compound is dimethylaluminum isopropoxide (DMAI), and the substrate temperature is 150° C. In some embodiments, the alkylaluminum compound is dimethylaluminum isopropoxide (DMAI), and the substrate temperature is 300° C. In some embodiments the catalytic chemical is an alkylboron compound, such as TEB, and the substrate temperature is between 50° C. and 400° C., or between 100° C. and 350° C., or between 100° C. and 300° C. In some embodiments the catalytic chemical is an alkylboron compound and the substrate temperature is greater than 100° C. In some embodiments the deposition temperature is greater than 300° C. and the catalytic chemical is TEB. The temperature of the catalyzation can be selected according to the passivation layer used to allow the use of single deposition temperature.

Upon completion of the surface pre-treatment step 104, the method 100 can continue with the step of forming a metal silicate layer on the treated dielectric surface (step 106), e.g., on the catalyzed silicon oxide surface of substrate 200 (FIG. 2). In accordance with examples of the disclosure, the step of forming a metal silicate layer on the dielectric surface comprises contacting the treated dielectric surface with an organosilanol precursor. In such examples, the dielectric layer is a silicon oxide layer (substrate 200) and the dielectric surface has been catalyzed to form a catalyzed silicon oxide surface. In such examples, the catalyzed silicon oxide surface is subsequently contacted with an organosilanol precursor to form a metal silicate threshold shifting layer on the catalyzed silicon oxide surface.

In accordance with examples of the disclosure, the organosilanol precursor comprises both an —OH group and an —OR group attached to a silicon atom, where R comprises a linear or branched C1-C10 alkyl group. In some embodiments, the organosilanol precursor comprises at least one alkoxy group and a —OH group attached to a silicon atom. In some embodiments, the organosilanol precursor comprises three alkoxy groups and a —OH group attached to a silicon atom. In some embodiments, the organosilanol precursor can comprise an alkoxysilanol. In such examples, the alkoxysilanol comprising a linear or branched, substituted or unsubstituted C1-C10 alkoxy group, or C1-C8 alkoxy group, and a OH-group attached to a silicon atom.

In some embodiments, the organosilanol precursors comprises more than one-OH group attached directly to a silicon atom. In some embodiments, the organosilanol precursor can include, without limitation, alkoxysilanols, alkoxyalkylsilanols, and alkoxysilanediols. In some embodiments, the organosilanol precursor is selected from a group consisting of tris(tert-butoxy)silanol (TBS), tris(isopropoxy)silanol (TIS), and tris(tert-pentoxy)silanol (TPS). A suitable silanol precursor can be selected by the skilled artisan such that it reacts with the catalyzed silicon oxide dielectric surface on the substrate to form a metal silicate dipole layer silicon dioxide under the desired reaction conditions.

In accordance with examples of the disclosure, a single organosilanol pulse is provided to the reaction chamber. In some embodiments a single organosilanol pulse is used to deposit the metal silicate dipole layer. In accordance with other examples of the disclosure, more than one silanol pulse is provided to the reaction chamber to form the metal silicate dipole layer. For example, a catalyst pulse can be followed by two, three or more organosilanol precursor pulses. In some embodiments, a catalyst pulse is followed by two organosilanol pulses. Each organosilanol precursor pulse may be separated by a purge step. In other embodiments, each organosilanol precursor pulse is provided after a predetermined time delay, without an intervening purge step. In accordance with examples of the disclosure, the organosilanol precursor is pulsed for a time period between 0.05 to 400 seconds, or between 0.1 to 400 seconds, or between 1 to 180 seconds, or between 30 to 180 seconds. The optimum pulsing time can be determined by the skilled artisan based on the particular circumstances.

In some embodiments, the temperature of the substrate during step 106 i.e., during the formation of the metal silicate via an organosilanol precursor, can be the same as the substrate temperature employed during step 104. In addition, method 100 of forming a metal silicate layer via an organosilanol precursor can include additional process steps not illustrated in FIG. 1. In accordance with examples of the disclosure, additional process steps can include additional chemical processes. In such examples, the additional process steps can include, the introduction of additional oxidizing agent(s) into the reaction chamber during the metal silicate formation process (step 106). In such examples, the additional oxidizing agent can be introduced into the reaction chamber with at least some temporal overlap with the introduction of the organosilanol precursor. Alternatively the additional oxidizing agent can be introduced into the reaction prior to and/or post the introduction of the organosilanol precursor to the reaction chamber. In accordance with further examples of the disclosure, additional process steps can include one or more post deposition treatments of the metal silicate layers formed according to the methods disclosed herein. In such examples, the metal silicate layers can be subject to post deposition treatment including, but not limited to, thermal annealing, microwave annealing, plasma treatments, cleaning treatments, and surface treatments.

### Section B: Metal Silicate Formation by Siloxide Precursors

In accordance with further examples of the disclosure, the metal silicate layers of the present disclosure can be formed by contacting a dielectric surface with a siloxide precursor. In such examples, the siloxide precursor comprises a single source precursor, wherein the term “single source precursor” can refer to a precursor which provides all the constituent elements of the layer being deposited. For example, the methods of the present disclosure enable the formation of metal silicate layers for use as ultra-thin dipole layers, the metal silicate layers having the general formula MSiₓO_{y}, where M is a metal element, Si is silicon, O is oxygen, and x and y indicate the composition of the metal silicate layer. Therefore, the embodiments of the disclosure, include methods for forming a metal silicate layer employing a single source precursor comprising a metal element, a silicon element, and an oxygen element. In such examples, a further oxidizing may not be required to form the desired metal silicate. In other examples, an additional oxidizing step can be performed by the introduction into the reaction chamber of an oxidizing agent.

Therefore, in accordance with some examples of the disclosure, the substrate comprises a dielectric surface which includes a silicon oxide surface and/or a high-k dielectric surface. In some embodiments, the dielectric surface comprises a high-k dielectric surface, as illustrated by substrate 300 of FIG. 2. In such examples the optional pre-deposition treatment (step 104) of method 100 (FIG. 1) can comprise one or more of a cleaning treatment, a surface preparation treatment, a surface functionalizing treatment, or a surface catalyzation treatment. In accordance with additional examples of the disclosure, the step of forming a metal silicate threshold voltage shifting layer on the dielectric surface comprises contacting the dielectric surface with a siloxide precursor. In such examples, the dielectric surface can be pre-treated by step 104 or the pre-treatment step 104 may be omitted.

In accordance with examples of the disclosure, upon completion of the optional surface pre-treatment (step 104), the method 100 can continue with the step of forming a metal silicate layer on the treated surface (step 106), e.g., the treated silicon oxide surface 206 of substrate 200 (FIG. 2) or the optionally treated high-k dielectric surface 308 of substrate 300 (FIG. 3). In some embodiments of the disclosure, forming the metal silicate threshold shifting layer on the dielectric surface comprises contacting the dielectric surface with a precursor comprising a siloxide precursor. In some embodiments of the disclosure, the siloxide precursor comprises a metal siloxide precursor.

In some embodiments, the temperature of the substrate during step 106 i.e., during the formation of the metal silicate via a siloxide precursor, can be the same as the substrate temperature employed during step 104.

In accordance with examples of the disclosure, the siloxide precursor comprises a single source precursor. In such examples, the siloxide precursor comprises a metal siloxide precursor. In some embodiments, the metal siloxide precursor comprises a single source precursor including one or more silicon atoms, metal atoms, and oxygen atoms. In some embodiments, the metal siloxide precursor comprises a single source precursor having the general formula M(OSiR₁R₂R₃)ₓL_{y}, where M is a metal, and each of R₁-R₃ are independently selected from a C1-10 alkyl group or a C1-10 alkoxyl group, where L is an organic ligand, and where y is equal to zero or greater than zero and the sum of x and y is equal to a valence of the metal (M). In some embodiments, the metal (M) is selected from a group consisting of rare earth elements, Zr, Al, Ga, Ti, Mg, Hf, Ta, V, Nb, Sr, Ca, and Ba. In some embodiments, the metal (M) is selected from a group consisting of Al, Ga, Ti, Hf, and Zr. In some embodiments, the metal (M) is Al. In some embodiments, the metal (M) is Hf. In some embodiments, the metal (M) is Ga.

In some embodiments, the siloxide precursor is a metal siloxide precursor. In such examples, the metal siloxide precursor can comprise a homoleptic siloxide precursor. In such embodiments, the homoleptic siloxide precursor comprises a single source precursor having the general formula M (OSiR₁R₂R₃) x, where M is a metal, and each of R₁-R₃ are independently selected from a C1-10 alkyl group or a C1-10 alkoxyl group, and x is equal to the valence of the metal (M). In some embodiments, the metal (M) is selected from a group consisting of rare earth elements, Zr, Al, Ga, Ti, Mg, Hf, Ta, V, Nb, Sr, Ca, and Ba. In some embodiments, the metal (M) is selected from a group consisting of Al, Ga, Ti, Hf, and Zr. In some embodiments, the metal (M) is Al. In some embodiments, the metal (M) is Ga. In some embodiments, the metal (M) is Hf. In some embodiments of the disclosure, the homoleptic siloxide precursor is selected from a group consisting of tetrakis(trimethylsiloxide)Zr, and tetrakis(trimethylsiloxide)Hf.

In some embodiments, the siloxide precursor is a metal siloxide precursor. In such examples, the metal siloxide precursor can comprise a heteroleptic siloxide precursor. In such examples, the heteroleptic siloxide precursor has the general formula M(OSiR₁R₂R₃)ₓL_{y}, where M is a metal, and each of R₁-R₃ are independently selected from a C1-10 alkyl group or a C1-10 alkoxyl group, where L is an organic ligand, and where y is greater than zero and the sum of x and y is equal to a valence of the metal (M). In such embodiments, the metal (M) is selected from a group consisting of rare earth elements, Zr, Al, Ga, Ti, Mg, Hf, Ta, V, Nb, Sr, Ca, and Ba. In some embodiments, the metal (M) is selected from a group consisting of Al, Ga, Ti, Hf, and Zr. In some embodiments, the metal (M) is Al. In some embodiments, the metal (M) is Hf. In such examples, the metal siloxide precursor can comprise the organic ligand (L) where L is selected from a group consisting of Cp (cyclopentadienyl) ligands, acac (acetylacetonate) ligands, and 2,2,6,6-tetramethylheptane-3,5-dionate (thd) ligands. In some embodiments, L is a tetramethylheptane-3,5-dionate (thd) ligand. In such embodiments, the heteroleptic siloxide precursor is selected from a group consisting of Zr-bis(trimethylsiloxide)-bis(thd), and Hf-bis(trimethylsiloxide)-bis(thd).

In accordance with further examples of the disclosure, the metal siloxide precursor can comprise a compound or complex having the general formula M[OSi(O^{t}Bu₃)]₄ where M is a metal selected from a group consisting of rare earth elements, Zr, Al, Ga, Ti, Mg, Hf, Ta, V, Nb, Sr, Ca, and Ba. In some embodiments, the metal (M) is selected from a group consisting of Al, Ga, Ti, Hf, and Zr. In some embodiments, the metal (M) is Al. In some embodiments, the metal (M) is Ga. In some embodiments, the metal (M) is Hf. In some embodiments, the metal siloxide precursor comprises Zr[OSi(O^{t}Bu)₃]₄. In some embodiments, the metal siloxide precursor comprises Hf[OSi(O^{t}Bu)₃]₄.

In accordance with examples of the disclosure, a single siloxide precursor pulse is provided to the reaction chamber. In some embodiments a single siloxide precursor pulse is used to deposit the metal silicate layer directly on the dielectric surface. In accordance with other examples of the disclosure, more than one siloxide precursor pulse is provided to the reaction chamber to form the metal silicate layer. Each siloxide precursor pulse may be separated by a purge step. In other embodiments, each siloxide precursor pulse is provided after a predetermined time delay, without an intervening purge step. In accordance with examples of the disclosure, the siloxide precursor is pulsed for a time period between 0.05 to 400 seconds, or between 0.1 to 400 seconds, or between 1 to 180 seconds, or between 30 to 180 seconds. The optimum pulsing time can be determined by the skilled artisan based on the particular circumstances.

In accordance with further examples of the disclosure, the method 100 of forming a metal silicate layer via siloxide precursors can include additional process steps not illustrated in FIG. 1. Such additional processes can be the same or similar to those described in “Section A” with reference to metal silicate formation methods employing organosilanol precursors and therefore such additional processes are not repeated here in the interest of brevity.

### Section C: Exemplary Metal Silicate Layer Properties and Structures Including Metal Silicate Layers

In accordance with examples of the disclosure, the metal silicates formed by the methods disclosure herein can be employed as threshold adjustment layers having a general formula MSiₓO_{y}, where M is a metal element, Si is silicon, O is oxygen, and x and y indicate the composition of the metal silicate layer. In some embodiments, the metal (M) is selected from a group consisting of rare earth elements, Zr, Al, Ga, Ti, Mg, Hf, Ta, V, Nb, Sr, Ca, and Ba. In some embodiments, the metal (M) is selected from a group consisting of Al, Ga, Ti, Hf, and Zr. In some embodiments, the metal (M) is Al. In some embodiments, the metal (M) is Ga. In some embodiments, the metal (M) is Hf. In some embodiments, the metal silicate layer is selected from a group consisting of an aluminum silicate, a gallium silicate, a titanium silicate, a hafnium silicate, and a zirconium silicate.

In accordance with examples of the disclosure, the metal silicate layers of the present disclosure are formed on a dielectric surface to an average layers thickness of less than 1.0 Å, or less than 0.9 Å, or less than 0.8 Å, or less than 0.7 Å, or less than 0.6 Å, or less than 0.5 Å, or less than 0.4 Å, or less than 0.3 Å, or less than 0.2 Å. In some examples, the metal silicate layers are formed on a dielectric surface to an average layers thickness of between 0.1 Å and 1 Å, or between 0.2 Å and 0.9 Å, or between 0.3 Å and 0.8 Å, or between 0.4 Å and 0.7 Å, or between 0.5 Å and 0.6 Å. In some embodiments of the disclosure, the metal silicate layers of the present disclosure can be formed as continuous layers. In some embodiment of the disclosure, the metal silicate layers can be formed as a discontinuous (i.e., non-continuous) layers.

In accordance with further examples of the disclosure, FIG. 2B illustrates a structure 400 which includes the substrate 200 after the formation of a metal silicate layer 402 on a silicon oxide surface. Although the metal silicate layer 402 is illustrated as a continuous layer it should be appreciated that the metal silicate layer 402 can be discontinuous. As illustrated, in such examples, the metal silicate layer 402 is disposed directly on a silicon oxide surface of a silicon oxide layer 204. In addition, FIG. 2C illustrates a structure 500 which includes a completed gate stack formed on the metal silicate layer 402. In accordance with examples of the disclosure, the gate stack is completed by the additional of a high-k dielectric layer 502 disposed on the threshold adjustment layer 402, and a gate electrode 504 disposed on the high-k dielectric layer 502.

In accordance with additional examples of the disclosure, FIG. 3B illustrates a structure 600 which includes the substrate 300 after the formation of a metal silicate layer 602 on a high-k dielectric surface. Although the metal silicate layer 602 is illustrated as a continuous layer it should be appreciated that the metal silicate layer 602 can be discontinuous. As illustrated, in such examples, the metal silicate layer 602 is disposed directly on the high-k dielectric surface of the high-k dielectric layer 306. In addition, FIG. 3C illustrates a structure 700 which includes a completed gate stack formed on the metal silicate layer 602. In accordance with examples of the disclosure, the gate stack is completed by the additional of a gate electrode layer 702 disposed on the threshold adjustment layer 602.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Indeed, various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of forming a metal silicate layer for controlling a threshold voltage of a metal-oxide-semiconductor field effect transistor (MOSFET), the method comprising the steps of:
seating a substrate within a reaction chamber, the substrate comprising a dielectric surface;
performing a pre-deposition treatment on the dielectric surface to form a treated dielectric surface, and
forming a metal silicate threshold voltage shifting layer directly on the treated dielectric surface by contacting the treated dielectric surface with a precursor comprising a siloxide precursor or an organosilanol precursor.

2. The method of claim 1, wherein the dielectric surface comprises a silicon oxide surface.

3. The method of claim 2, wherein the pre-deposition treatment comprises contacting the silicon oxide surface with a metal catalyst including a metal element selected from a group consisting of rare earth elements, Zr, Al, Ga, Ti, Mg, Hf, Ta, V, Nb, Sr, Ca, and Ba.

4. The method of claim 1, wherein the organosilanol precursor comprises both an —OH group and an —OR group attached to a silicon atom, where R comprises a linear or branched C1-C10 alkyl group.

5. The method of claim 1, wherein the organosilanol precursor comprises at least one alkoxy group and a —OH group attached to a silicon atom.

6. The method of claim 1, wherein the organosilanol precursor comprises three alkoxy groups and a —OH group attached to a silicon atom.

7. The method of claim 1, wherein the organosilanol precursor is selected from a group consisting of tris(tert-butoxy)silanol (TBS), tris(isopropoxy)silanol (TIS), and tris(tert-pentoxy)silanol (TPS).

8. The method of claim 1, wherein the siloxide precursor comprises a single source precursor having the general formula M(OSiR₁R₂R₃)ₓL_{y}, where M is a metal, and each of R₁-R₃ are independently selected from a C1-10 alkyl group or a C1-10 alkoxyl group, where L is an organic ligand, and where y is equal to zero or greater than zero and the sum of x and y is equal to a valence of the metal (M).

9. The method of claim 8, wherein the siloxide precursor has the general formula M[OSi(O^{t}Bu)₃]₄ where M is a metal selected from a group consisting of Al, Ga, Ti, Hf, and Zr.

10. A method of forming a metal silicate layer for controlling a threshold voltage of a metal-oxide-semiconductor field effect transistor (MOSFET), the method comprising the steps of:
seating a substrate within a reaction chamber, the substrate comprising a dielectric surface including a silicon oxide surface and/or a high-k dielectric surface; and
depositing a metal silicate threshold voltage shifting layer directly on the dielectric surface by contacting the dielectric surface with a metal siloxide precursor, the metal siloxide precursor comprising a single source precursor including one or more silicon atoms, metal atoms, and oxygen atoms.

11. The method of claim 10, wherein the metal siloxide precursor has the general formula M(OSiR₁R₂R₃)ₓL_{y}, where M is a metal selected from a group consisting of rare earth elements, Zr, Al, Ga, Ti, Mg, Hf, Ta, V, Nb, Sr, Ca, and Ba, and where each of R₁-R₃ are independently selected from a C1-10 alkyl group or a C1-10 alkoxy group, where L is an organic ligand, and where y is equal to zero or greater than zero, and the sum of x and y is equal to a valence of the metal (M).

12. The method of claim 11, wherein the metal siloxide precursor is a homoleptic siloxide precursor.

13. The method of claim 12, wherein the homoleptic siloxide precursor is selected from a group consisting of tetrakis(trimethylsiloxide)Zr, and tetrakis(trimethylsiloxide)Hf.

14. The method of claim 11, wherein the siloxide precursor is a heteroleptic siloxide precursor.

15. The method of claim 14, wherein the heteroleptic siloxide precursor comprises the organic ligand (L) where L is selected from a group consisting of Cp (cyclopentadienyl) ligands, acac (acetylacetonate) ligands, and 2,2,6,6-tetramethylheptane-3,5-dionate (thd) ligands.

16. The method of claim 15, wherein the heteroleptic siloxide precursor is selected from a group consisting of Zr bis(trimethylsiloxide) bis(thd), and Hf bis(trimethylsiloxide) bis(thd).

17. A method for depositing a threshold voltage shifting layer on a dielectric surface by a deposition process, the threshold voltage shifting layer having a chemical formula containing a metal element, a silicon element, and an oxygen element, wherein a single source precursor comprising a metal siloxide precursor is used as a source for the metal element, the silicon element, and the oxygen element, and wherein the dielectric surface comprises a silicon oxide surface and/or a high-k dielectric surface.

18. The method of claim 17, wherein the metal siloxide precursor comprises a compound having a general formula M[OSi(O^{t}Bu₃)]₄ where M is a metal selected from the group consisting of Al, Ga, Ti, Hf, and Zr.

19. The method of claim 18, wherein the threshold voltage adjustment layer is selected from a group consisting of an aluminum silicate, a gallium silicate, a titanium silicate, a hafnium silicate, and a zirconium silicate.
